(19) United States
(12) Patent Application Publication
(10) Pub. No.: US 2009/0021240 A1
(43) Pub. Date: Jan. 22, 2009

(54) CIRCUIT TESTER/JUMPER

(75) Inventors: Steven J. Wherley, Carver, MN (US); Randall J. Ploeger, Clarinda, IA (US)

Correspondence Address: BANNER & WITCOFF, LTD., TEN SOUTH WACKER DRIVE, SUITE 3000, CHICAGO, IL, 60606, US

(73) Assignee: Lisle Corporation, Clarinda, IA (US)

(21) Appl. No.: 11/779,985

(22) Filed: Jul. 19, 2007

(51) Int. Cl. G01R 19/14

(52) U.S. Cl. 324/133

(57) ABSTRACT

A device which may be utilized as a circuit testing device or a power source conductor device includes a handle with a single lead wire electrically connected to a light in series circuit with a probe. Further included is a push button switch on the side of the handle which may be manually moved to disengage the light from the circuit and simultaneously enable a series circuit directly to the probe to thereby provide a power source.

### BACKGROUND OF THE INVENTION

In a principal aspect the present invention relates to a circuit tester useful for testing a circuit and alternatively to provide power to a circuit.

Auto mechanics and repairmen often find it necessary to test an electrical circuit when conducting repair operations. Further, there are situations where the repair operation necessitates providing power to a device in order to check or investigate the operability of the device. Various products are available or are the subject of patents that enable such testing or alternatively to provide power from a power source to a device which is being tested for operability. By way of example, U.S. Pat. No. 4,540,940 entitled Circuit Tester for Automotive Electrical Systems depicts such a device. Lisle Corporation also manufactures tools of this general nature identified as Product Nos. 26250; 25600; 28400; 29500; 27450; 26200; and 28640. One or more of these products are within the scope of claims of U.S. Pat. No. 4,716,365 and/or U.S. Pat. No. 6,433,530, both of which are incorporated herein by reference.

Such devices are very beneficial and quite useful for their designed purpose. A design for such devices is represented by the subject matter of U.S. Pat. No. 4,540,940. The device disclosed may be used to test a circuit to insure the circuit is powered or to provide power to a component such as a fan motor. Capability of providing a means to check a circuit as well as to provide a power source in a simple, yet highly functional and rugged tool or device is considered desirable.

### SUMMARY OF THE INVENTION

Briefly, the present invention comprises a tool or device which includes a handle having a conductive probe projecting from one end thereof and a lead wire extending through a threaded cap fitted into and threaded into a hollow bore of the handle member at the opposite end thereof.

The handle member or handle is comprised of a non-conductive material such as a plastic material. The handle member has a longitudinal axis extending from a conductive contact of the lead wire to the end of the conductive probe located in the hollow bore of the handle. Electrical contacts are provided at the opposite ends of the interior, hollow, generally cylindrical chamber in the handle. A biasing element as well as a light element are connected between the two contacts. Thus, a circuit may be tested by attaching the lead wire to a power source and then engaging the probe with the wire or item which is to be checked. If the light element is energized, then circuit power is confirmed.

To bypass the light and biasing spring, a switch is built into the handle. The switch comprises a push button which extends transversely to the axis from the hollow core. The push button may be engaged with a cantilever spring blade within the hollow core to position that spring blade as an alternate, direct circuit between the two contacts within the hollow core of the insulating handle. Thus, pressing the push button enables bypassing the indicator light to provide power directly to the probe and any component electrically engaged by the probe. The probe may thereby engage a device to determine the operability of the device.

Thus, it is an object of the invention to provide a single tool or device which may be utilized to test a circuit for power as well as provide a power source via a single lead wire.

It is a further object of the invention to provide a testing device which has a construction which is rugged, easy to assemble, easy to repair and wherein the component parts may be easily replaced.

Another object of the invention is to provide a tester and power source unified in a single tool wherein the device has a single lead wire, is compact, lightweight and easy to use.

These and other objects, advantages and features of the invention will be set forth in the detailed description which follows.

### BRIEF DESCRIPTION OF THE DRAWING

In the detailed description which follows, reference will be made to the drawing comprised of the following figures:

FIG. 1 is a cross sectional view of an embodiment of the invention;

FIG. 2 is a circuit diagram depicting the alternative circuits associated with the tool of FIG. 1; and

FIG. 3 is an exploded isometric view of the tool of FIG. 1.

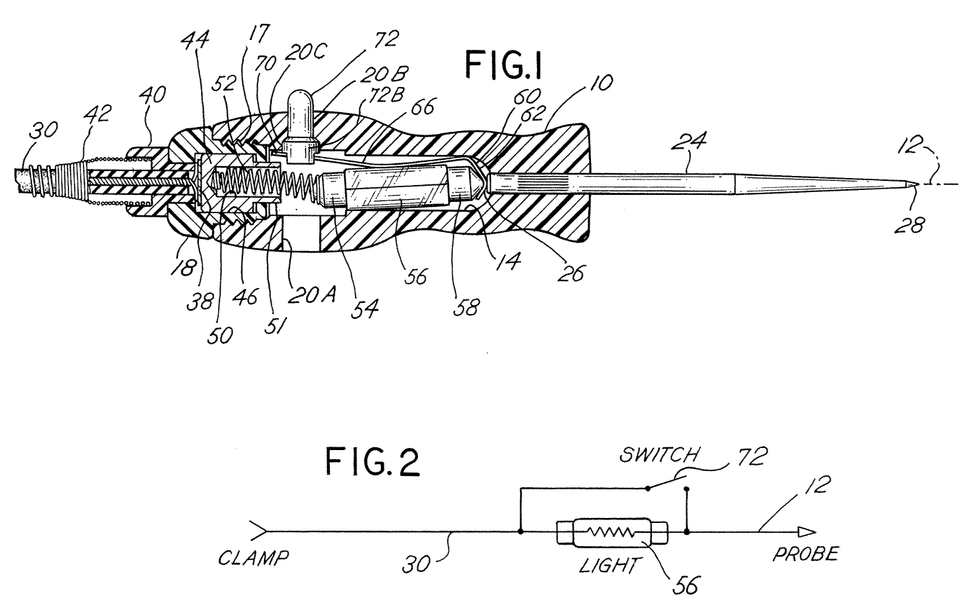

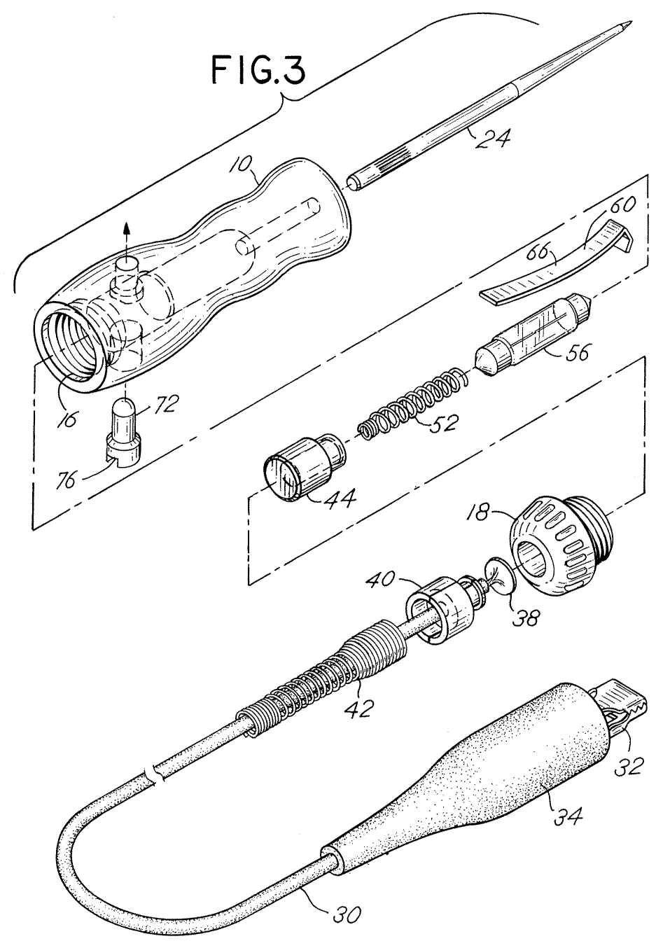

### DESCRIPTION OF AN EMBODIMENT OF THE INVENTION

Referring to the figures, the test device which provides for the possibility of investigating whether a circuit is powered or which may act as a power source includes a handle member or handle 10. The handle 10 is generally cylindrical and is configured on its outer surface in the shape, for example, of a screwdriver handle or some other similar elongate cylindrical handle for ease of gripping and comfort. The handle 10 is comprised of an insulating material, for example, a molded plastic material. The handle 10 includes a generally longitudinal axis of symmetry 12. An axial hollow chamber 14 is defined in the interior of the handle 10. The hollow chamber 14 extends from the forward interior end of the handle 10 through an open end 16 which includes internal threads 17 for attachment of a cap 18. The handle 10 further includes a transverse through passage comprising passage sections 20A and 20B. The passage is transverse to the axis 12 and intersects with the axis 12. The passage defined by the passages 20A and 20B extends into the, and through the, hollow chamber 14 and is comprised of a relatively larger diameter passage 20A and a relatively smaller diameter passage 20B with a small counterbore section 20C.

A conductive metal probe 24 extends axially outwardly from the handle 10 and inwardly projects into the chamber or hollow section 14 to define a first contact 26. The probe 24 comprises a conductive rod with a distal end point 28 which may be engaged with, for example, or to penetrate an insulated wire in order to investigate if a circuit is powered.

The device further includes a single lead wire 30 which is insulated and connects with an alligator clip or contact 32 at its outer end. A shroud 34 is fitted over the alligator clip 32. The lead wire 30 is insulated and connects with a contact 38 soldered to its inner end. An insulated fitting 40 fits over the lead wire 30 and engages with a protective coil spring 42 to hold the lead wire 30 snugly in cap 18. The contact 38 engages a cylindrical contact element 44 which is held in place within a hollow counterbore 46 of the cap 18. The cap 18 is threaded on its outer surface so that it will engage with the threads 17 to hold the contact element 44 in position projecting into the chamber 14. The elements described are generally symmetrical about the longitudinal axis 12.

The contact device or element 44 is comprised of a conductive material, for example, copper, and includes a counterbore 50 which receives a conductive spiral spring 52. The spiral spring 52 fits into engagement with a first conductive end or contact 54 of a light element or light 56 having its opposite conductive end or contact 58 aligned axially with the first contact 26 of the probe 24. The spiral spring 52 and light element 56 are thus generally aligned in series axially aligned with axis 12.

A cantilever spring member 60 includes a first arm 62 which fits between contact 58 of light 56 and the first contact 26 at the end of a probe 24. The cantilever spring 60 further includes a cantilever arm 66 which extends generally axially and is spaced radially from the axis 12 in the interior and along the top side of the hollow chamber 14. The spring 60 and, more particularly, the cantilever arm 66 is biased outwardly away from and radially spaced from the axis 12 so that the extreme end 70 of conductive spring 60 will typically not be engaged with an outer rim 51 of the contact member 44. A push button 72 having a smaller diameter end that is compatible with the passage 20B and a larger diameter end 72B which enables it to fit through the opening 20A includes a slot 76 which fits over the distal end of the cantilever arm 66 of the spring 60. Thus, the push button 72 is held in alignment by engagement with the cantilever spring 60 and further maintains the cantilever spring 60 properly aligned within the hollow chamber 14 by virtue of its engagement with the push button 72.

The push button 72 is normally biased outwardly in the passage 20B by arm 66. Thus, the device will typically enable testing whether a line is powered inasmuch as the light 56 is in the circuit. However, when the switch, which is represented by the push button 72, is closed, the light 56 is bypassed and electricity may flow in series through the cantilever spring 60 directly to the probe 12 to thereby provide power to a device and check the operability of the device. In this manner, power may be supplied to a fan motor or some other apparatus in an automobile.

It is to be noted then that the push button 72 provides multiple functions. It maintains alignment of the cantilever spring 60. It provides a means to change the circuitry within the device by engaging the cantilever spring 60 with the contact 44. The push button 72 is sized in cooperation with the openings 20A, 20B and 20C so that it may be inserted during assembly of the tool through the larger diameter opening 20A and project outwardly through the smaller diameter opening 20B without passing therethrough.

In the event any component parts within the interior of the device need to be changed or repaired, the handle 10 may then be disengaged from the cap 18 by unthreading the handle 10 therefrom. In this manner, the component parts within the interior of the hollow chamber 14 may be removed. For example, the spring 52 and light 56 may be removed and replaced. Thus, the device may be easily repaired.

Further, the device may originally be easily assembled inasmuch as the push button 72 will first be inserted through the passages 20A and 20B to the position depicted, for example, in FIG. 1. Therefore, the cantilever spring 60, the light 56, the conductive spiral spring 52 and the contact element 44 may all be inserted and maintained by threading the cap 18 into the handle 10.

In sum, the device enables circuit testing, enables acting as a power source and enables easy repair and replacement of parts should any of the component parts become damaged. Further, the component parts are maintained in appropriate alignment and engagement to insure that the operational functions of the device will be maintained as designed.

Various changes may be made to the invention without departing from the spirit and scope thereof. For example, the push button 72 may have a cross sectional profile which is non-circular. The invention, therefore, is to be limited only by the following claims and equivalents thereof.

What is claimed is:

1. A circuit testing and power source conductor device comprising in combination:
an insulating, generally cylindrically configured handle having a longitudinal axis and a generally axial, hollow core open at one end of the handle;
a conductive probe member extending from the hollow core axially from the end of the handle opposite the open end;
a removable cap at said one end of the handle for closing the open end of the handle;
a single conductive lead extending through the cap to the interior of the hollow core;
a first conductive contact in the hollow core connected to the conductive lead;
a second conductive contact in the hollow core connected to the probe member at the opposite end of the hollow core;
a conductive biasing element and a light element in series connected between the first contact and the second contact;
a conductive cantilever spring member connected at one end to one of said first and second contacts and displaceable to connect in series to the other of said first and second contacts, said conductive cantilever spring member normally biased out of electrical contact with said other contact member thereby providing a circuit testing device; and
an insulated push button slidably mounted in the handle for movement generally transverse to the axis and positioned to engage and move the cantilever spring member to connect to said other contact member to thereby electrically bypass the biasing element and light element and provide a series power source conductor.

2. The device of claim 1 wherein the handle includes a transverse through passage for receipt of the push button, said passage having a first larger diameter passage to the hollow core and a second smaller diameter passage to the hollow core aligned with the first passage, and said push button includes a compatible actuation end inserted in and projecting from the smaller diameter passage and a cantilever spring engaging end passable through the larger diameter passage, said spring engaging end greater in diameter than the smaller diameter passage diameter.

3. The device of claim 1 wherein the biasing element and light element are generally aligned with the axis.

4. The device of claim 2 wherein the biasing element and light element are generally aligned with the axis and the spring member is, in part, radially spaced from the axis and aligned with the path of movement of the push button.

5. The device of claim 3 wherein the biasing element is a spiral spring having a longitudinal axis aligned between the light element and one of said contacts.
